(19) United States
(12) Patent Application Publication
(10) Pub. No.: US 2004/0102041 A1
(43) Pub. Date: May 27, 2004

(54) Method of manufacturing semiconductor device with capacitor electrode

(75) Inventor: Tomonori Okudaira, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/690,745

(22) Filed: Oct. 23, 2003

(30) Foreign Application Priority Data
Nov. 25, 2002 (JP) 2002-340733

(51) Int. Cl. H01L 21/302; H01L 21/461

(52) U.S. Cl. 438/689

(57) ABSTRACT

Ru or Os is used for the main constituent of a mask film employed in patterning a capacitor electrode mainly made of Pt or Ir. As compared to the case of using a silicon oxide film for an etching mask for Pt or Ir, the thickness of a Ru film or Os film is only about one tenth that of the silicon oxide film. Thus, the aspect ratio of a patterning mask on Pt is as low as about 1 to 2. As a result, problems such as pattern collapse hardly arise.

### BACKGROUND OF THE INVENTION

1. Field of the Invention

The present invention relates to a method of manufacturing a semiconductor device including capacitors.

2. Description of the Background Art

In a semiconductor device such as DRAM (Dynamic Random Access Memory), a great number of capacitors are formed. In a conventional capacitor, doped polysilicon has been used for its electrode material, and silicon oxide or silicon nitride has been used for its dielectric material.

With increasing integration of semiconductor devices, further reduction of a capacitor electrode area has been required. In order to avoid reduction in electrostatic capacity of capacitors while reducing the electrode area, the dielectric constant of dielectric materials needs to be increased.

Therefore, high dielectric materials such as BST (barium strontium titanate) have been used for dielectric materials of capacitors in place of conventional materials. Following this, metal materials such as platinum (Pt) and iridium (Ir) which hardly react with such high dielectric materials have been used for electrode materials of capacitors.

However, Pt and Ir are difficult to treat, which requires improvements in patterning methods. For instance, there is a treatment method of patterning metal materials by sputter etching. With this method, metal materials can relatively easily be treated, but are difficult to pattern in accordance with the shape of a patterning mask. This is because sputter etching tends to cause metal materials to taper with the bottom portion being wider than the top portion.

Therefore, high temperature etching technique has been developed as a method of chemically treating metal materials. When treating Pt, for example, a silicon oxide film is used as a patterning mask and is formed on Pt. Openings of the patterning mask are exposed to chlorine gas to form platinum chloride therein. At this time, heating a semiconductor substrate on which Pt is formed to a high temperature causes the chloride portion of Pt to volatilize, whereby patterning can be performed.

This method allows Pt of several hundred nanometers thickness to be formed with a taper angle of 85° or greater, which means it tapers little. Thus, the high temperature etching technique can be a treatment method suitable for fine patterning of capacitor electrodes.

The following documents present the background art of the present invention: Japanese Patent Application Laid-Open Nos. 2000-183303; 2000-223671; 8-330538; and 9-199687.

In the above-described high temperature etching technique, the etch rate of Pt is improved as heating temperature is set higher. On the other hand, the etch rate of silicon oxide is not temperature-dependent. Thus, the etch selectivity of Pt to silicon oxide is improved as heating temperature is set higher. Therefore, it is preferable to rise temperature as high as possible in order to improve the etch selectivity.

However, there is a factor that hinders rise in temperature. Pt has a melting point of about 1800° C., which is relatively higher than those of other metals, but actually causes a phase change at about 500° C., resulting in cohesion. This cohesion phenomenon tends to occur at lower temperatures as Pt is desired to be formed more finely. It is therefore necessary to keep the semiconductor substrate on which Pt is formed at about 330-370° C. in order to form Pt to have an electrode width of about 0.10 μm.

Within such range of treatment temperatures, the etch rate of silicon oxide to Pt ranges between about 1:0.25 and 1:0.5. That is, to form Pt of, e.g., 300 nm thickness to have an electrode width of about 0.10 μm, a silicon oxide film mask of about 800 nm thickness is required, increasing the aspect ratio of the patterning mask to nearly as high as 10.

In the case where Pt needs to be formed in a narrow island shape as in formation of capacitor electrodes, such patterning mask having a high aspect ratio causes pattern collapse. This applies not only to Pt but also to Ir.

With such problems, it has been difficult to form a capacitor electrode having an electrode width of about 0.1 to 0.21 μm even with the high temperature etching technique.

### SUMMARY OF THE INVENTION

It is therefore an object of the present invention to provide a method of manufacturing a semiconductor device containing Pt or Ir as an electrode material of capacitors, suitable for manufacture with the high temperature etching technique.

According to an aspect of the present invention, a method of manufacturing a semiconductor device includes the following steps (a) through (e). The step (a) is to form a capacitor electrode metal film mainly made of one of Pt and Ir on an underlying layer. The step (b) is to form a first mask film mainly made of one of Ru and Os on said capacitor electrode metal film. The step (c) is to selectively open said first mask film. The step (d) is to expose an uncovered part of said capacitor electrode metal film at an opening of said first mask film to a predetermined gas atmosphere so as to volatilize while heating said capacitor electrode metal film, thereby selectively etching said capacitor electrode metal film. The step (e) is to remove said first mask film.

The capacitor electrode metal film mainly made of Pt or Ir is selectively etched using the first mask film mainly made of Ru or Os as a patterning mask. The use of Ru or Os for a mask material can minimize the aspect ratio of a mask. Thus, pattern collapse hardly occurs different from the case of using silicon oxide for a mask material. As a result, achieved is a method of manufacturing a semiconductor device containing Pt or Ir as an electrode material of capacitors, suitable for manufacture with the high temperature etching technique. Further, according to the present invention, the first mask film is removed. In the case of using Ru for the main constituent of the first mask film, problems of increase in a leakage current resulting from the contact with the dielectric film and variations in volume of the capacitor electrode due to oxidation of Ru may arise if the first mask film remains unremoved and constitutes the capacitor lower electrode together with the capacitor electrode metal film. Such problems do not arise in the present invention since the first mask film is removed.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 10 illustrate a method of manufacturing a semiconductor device according to a first preferred embodiment of the present invention;

FIG. 11 illustrates taper of a lower electrode;

FIGS. 12 through 17 illustrate a method of manufacturing a semiconductor device according to a second preferred embodiment of the invention; and

FIGS. 18 through 24 illustrate a method of manufacturing a semiconductor device according to a third preferred embodiment of the invention.

### DESCRIPTION OF THE PREFERRED EMBODIMENTS

First Preferred Embodiment

The first preferred embodiment is directed to a method of manufacturing a semiconductor device in which ruthenium (Ru) or osmium (Os) is used for a mask film employed in patterning Pt or Ir which is an electrode material of capacitors.

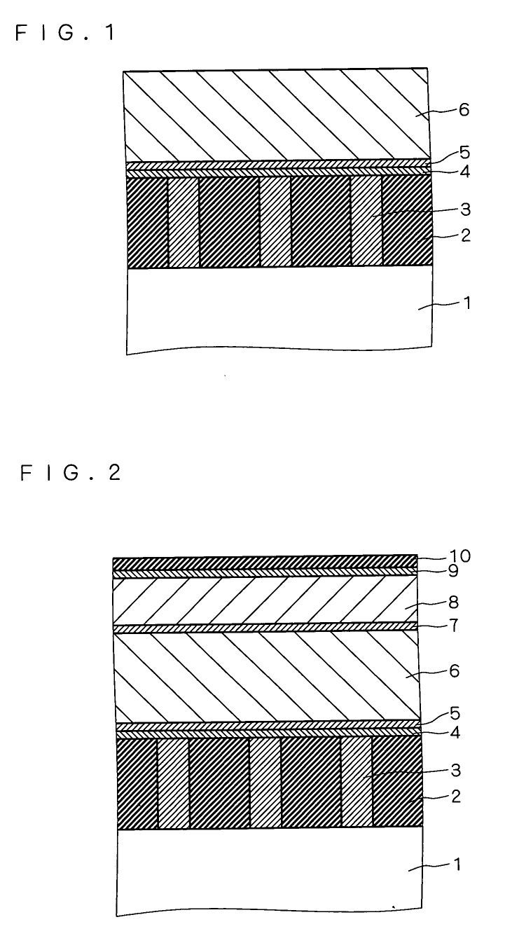

FIGS. 1 through 10 illustrate respective steps of the method according to the present embodiment.

First, as shown in FIG. 1, an interlayer dielectric 2 made of, e.g., silicon oxide is formed on a semiconductor substrate 1 made of, e.g., silicon. Then, contact holes are formed in the interlayer dielectric 2 to penetrate therethrough by photolithography and etching. The contact holes are thereafter filled with titanium nitride, and the surface is planarized by CMP (chemical mechanical polishing) or the like, thereby forming conductive plugs 3. Since the structure formed by the semiconductor substrate 1, interlayer dielectric 2 and conductive plugs 3 can be considered as an underlying layer on which a capacitor electrode is to be formed, the structure will hereinafter be called an underlying layer throughout the description of this invention.

Subsequently, a titanium (Ti) film 4, a titanium nitride (TiN) film 5 and a platinum (Pt) film 6 for a lower electrode are formed in this order on the underlying layer by sputtering, for example. The Ti film 4 and TiN film 5 may each be of 10 nm thickness, and the Pt film 6 may be of 300 nm thickness, for example.

Ti film 4 is in contact with the conductive plugs 3 and is interposed between the Pt film 6 and conductive plugs 3 for connecting both. This film functions as an adhesion layer for improving adhesion between the conductive plugs 3 and Pt film 6. Another material may suitably be selected to perform the same function as the Ti film 4. When there is no need to improve adhesion, the adhesion layer may be omitted.

The TiN film 5 is interposed between the Pt film 6 and Ti film 4 for connecting both and functions as an anti-diffusion layer. Without such anti-diffusion layer, heat treatment and the like in forming a capacitor dielectric film may cause interdiffusion of atoms between the Pt film 6 and conductive plugs 3. Such interdiffusion may generate voids in the conductive plugs 3, for example. The TiN film 5 serves to avoid such interdiffusion. However, such anti-diffusion layer may be omitted when such interdiffusion occurs with little possibility or causes no problem.

As a material other than TiN, at least one of metal oxide, metal nitride, metal silicide, metal oxynitride, metal silicon-oxide, metal silicon-oxynitride and metal silicon-nitride may suitably be selected, to perform the same function as the TiN film 5.

Further, the Pt film 6 may be made of Ir instead of Pt.

Next, as shown in FIG. 2, a first mask film 8 mainly made of Ru or Os is formed on the Pt film 6. In the present embodiment, a TiN film 7 similar to the TiN film 5 is formed as an anti-diffusion layer between the first mask film 8 and Pt film 6. The first mask film 8 and TiN film 7 are each formed by sputtering, for example.

As a material other than TiN, at least one of metal oxide, metal nitride, metal silicide, metal oxynitride, metal silicon-oxide, metal silicon-oxynitride and metal silicon-nitride may suitably be selected, to perform the same function as the TiN film 7. The TiN film 7 may be of 10 nm thickness and the first mask film 8 may be of 150 nm thickness, for example.

The TiN film 7 functions as an anti-diffusion layer. Without this anti-diffusion layer, heat treatment and the like in high temperature etching of the Pt film 6 may cause interdiffusion of atoms between the first mask film 8 and Pt film 6. Such interdiffusion may reduce the taper angle of the Pt film 6, for example. The TiN film 7 serves to avoid such interdiffusion. However, the anti-diffusion layer may be omitted when such interdiffusion occurs with little possibility or causes no problem.

Further, a second mask film 10 mainly made of silicon oxide or silicon nitride is formed on the first mask film 8 employed in patterning the first mask film 8. Silicon oxide or silicon nitride which is the main constituent of the second mask film 10 has a high etch selectivity to Ru or Os which is the main constituent of the first mask film 8. This allows selective opening of the first mask film 8 to be performed with high accuracy.

In the present embodiment, a TiN film 9 is formed between the second mask film 10 and first mask film 8 as an adhesion layer to improve adhesion between both the films. The TiN film 9 is formed by, e.g., sputtering, and the second mask film 10 by, e.g., CVD (chemical vapor deposition).

As a material other than TiN, at least one of metal oxide, metal nitride, metal silicide, metal oxynitride, metal silicon-oxide, metal silicon-oxynitride and metal silicon-nitride may suitably be selected, to perform the same function as the TiN film 9. The TiN film 9 may be of 10 nm thickness and the second mask film 10 may be of 20 nm thickness, for example.

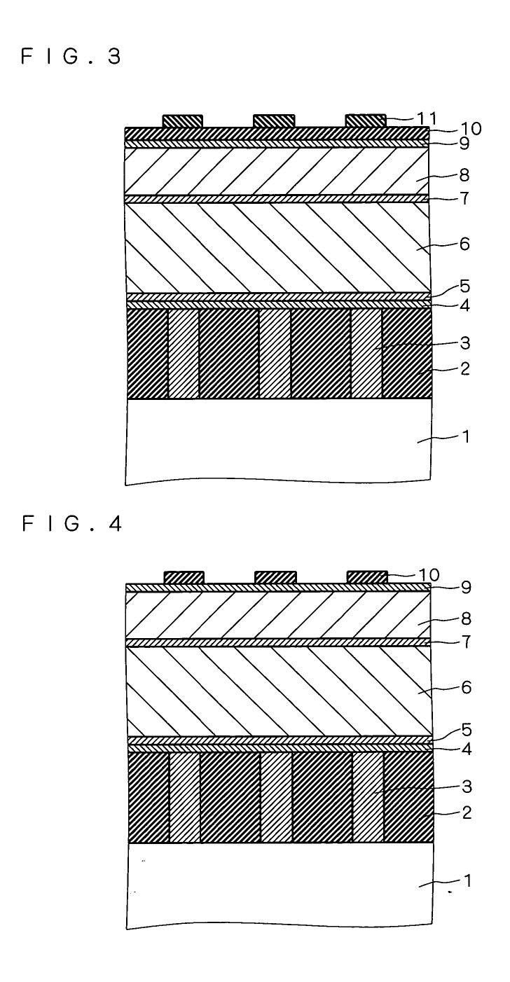

Next, as shown in FIG. 3, a photoresist 11 is formed on the second mask film 10 and is patterned by photolithography. Then, the second mask film 11 is dry etched with mixed gas of CF₄ and O₂, for example, using the photoresist 11 as an etching mask, and the photoresist 11 is removed. The second mask film 10 is thereby patterned as shown in FIG. 4.

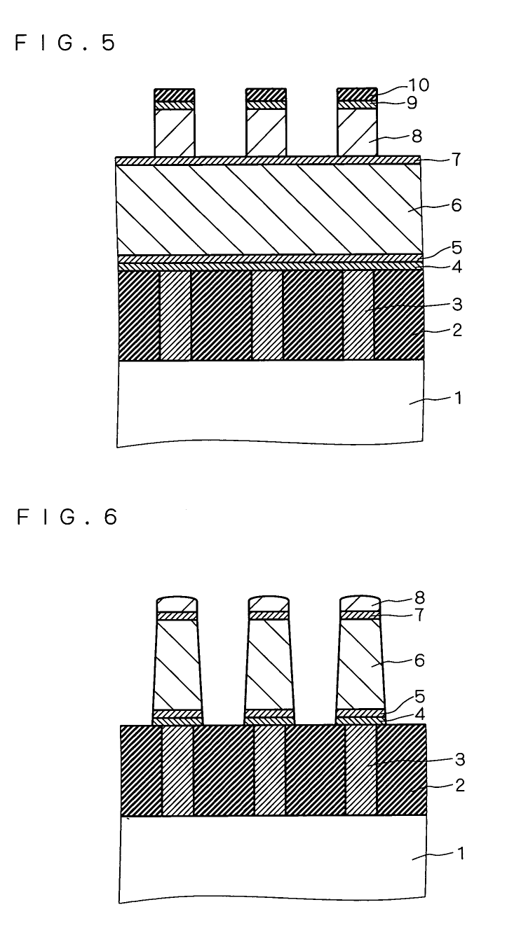

Next, as shown in FIG. 5, the TiN film 9 and first mask film 8 are etched using the second mask film 10 as an etching mask. Etching of the TiN film 9 may be carried out using, e.g., a helicon wave plasma etching system under the following conditions: substrate temperature of 30-60° C.; mixed gas of Cl₂ and Ar (Cl₂—Ar gas flow rate of 5:1 to 9:1); inner pressure of 3-10 mTorr; source power of 1 kW; and bias power of 100 W. Etching of the first mask film 8 may be carried out using, e.g., a helicon wave plasma etching system under the following conditions: substrate temperature of 30-60° C.; mixed gas of O₂ and Cl₂ (O₂—Cl₂ gas flow rate of 5:1 to 10:1); inner pressure of 3-10 mTorr; source power of 1 kW; and bias power of 100 W.

The above conditions are only illustrative, and an etching system of another type of generating plasma or other etching conditions may be employed.

Since a silicon oxide film and silicon nitride film are etched little under the above etching conditions, the second mask film 10 mainly made of either one of these films functions as an etching mask for the first mask film 8. The patterned first mask film 8 tapers little.

Next, as shown in FIG. 6, the TiN film 7, Pt film 6, TiN film 5 and Ti film 4 are etched using the first mask film 8 and second mask film 10 as an etching mask. Etching of these films may be carried out using, e.g., an ICP (inductively coupled plasma) etching system under the following conditions: substrate temperature of 330-370° C.; mixed gas of Cl₂ and Ar (Cl₂—Ar gas flow rate of 8:1 to 20:1); inner pressure of 10-30 mTorr; source power of 750 W-1.6 kW; and bias power of 150-350 W. At the end of etching, the first mask film 8 has a reduced thickness as shown in FIG. 6 since the second mask film 10 and TiN film 9 have been removed by etching and the first mask film 8 has also been etched to some degree.

Exemplary numerical values in the case of using Ru for the main constituent of the first mask film 8 as an etching mask for the Pt film 6 are as follows: in an ICP etching system, the etch rate of silicon oxide to Pt ranges between about 1:0.2 and 1:0.3 whereas that of Ru to Pt ranges between about 1:1.8 and 1:3.0 under the following conditions: substrate temperature of 350° C.; mixed gas of Cl₂ and Ar (Cl₂—Ar gas flow rate of 10:1 to 20:1); inner pressure of 10-30 mTorr; source power of 800 W-1.6 kW; and bias power of 200-300 W.

Therefore, to form Pt of 300 nm thickness to have an electrode width of 0.10 μm, a silicon oxide film needs to have a thickness of about 1.0 to 1.5 μm, whereas a Ru film only needs to have a thickness of about 100 to 170 nm. That is, the thickness of the Ru film is about one tenth that of the silicon oxide film, and hence, the aspect ratio of the patterning mask on Pt is as low as about 1 to 2. As a result, problems such as pattern collapse of mask hardly arise. When using Os for the main constituent of the first mask film 8, the numerical values are the same as those for Ru.

Upon completion of etching of the TiN film 7, Pt film 6, TiN film 5 and Ti film 4, the remaining part of the first mask film 8 and TiN film 7 thereunder are removed as shown in FIG. 7. Removal of these films may be carried out by etching under the same conditions for etching the TiN film 9 and first mask film 8 as described referring to FIG. 5.

Now, advantages of removing the first mask film 8 will be described. In the case of using Ru for the main constituent of the first mask film 8, problems may arise in connection with a dielectric film to be formed later if the first mask film 8 remains unremoved and constitutes the lower electrode together with the Pt film 6.

Specifically, the following two problems may arise. First, Ru having a work function smaller than that of Pt may increase a leakage current due to the contact with the dielectric film such as BST film to be formed later.

The other problem is oxidation of Ru due to formation of the dielectric film such as BST film in an oxidizing atmosphere. Ru oxide is an unstable material, and hence, if the first mask film 8 remains unremoved and constitutes the lower electrode together with the Pt film 6, Ru oxide may emit oxygen in high temperature annealing or the like in a later process, causing shrinkage of the lower electrode, and may generate a void between itself and the dielectric film.

However, the first mask film 8 is removed in the present invention, which avoids occurrence of such problems.

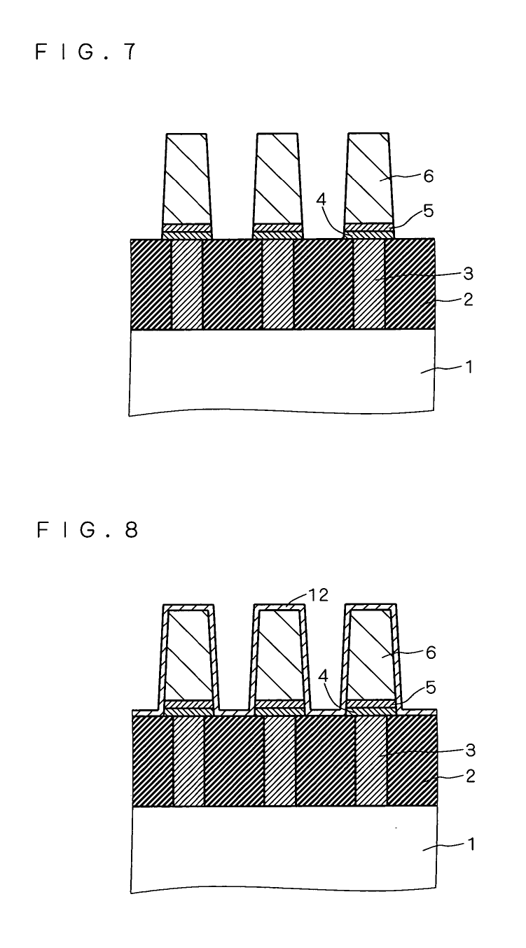

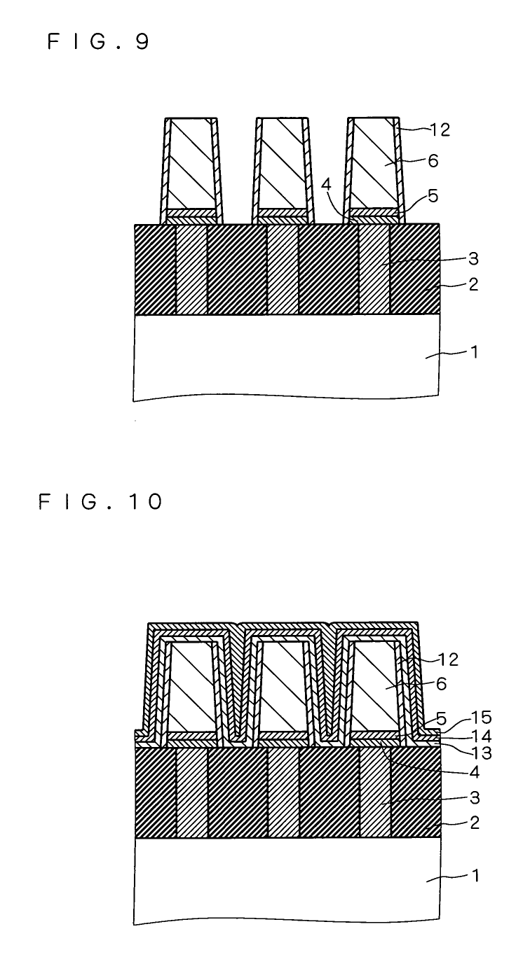

Subsequently, as shown in FIG. 8, a contact-preventing Pt film 12 is deposited on the entire surface of the semiconductor substrate. Then, as shown in FIG. 9, etch back is performed to form the Pt film 12 so as to cover the sides of the Pt film 6, TiN film 5 and Ti film 4. The Pt film 12 is provided to prevent the dielectric film to be formed later from being in contact with the TiN film 5 and Ti film 4.

When a BST film is employed for the dielectric film, the contact of the BST film with the TiN film 5 and Ti film 4 may cause reduction in a breakdown voltage. The BST film is a supply source of oxygen, which easily causes oxidation-deoxidation reaction with respect to these films. Deoxidation of BST will generate a void, increasing a leakage current, which easily causes reduction in breakdown voltage.

Therefore, the uncovered parts of the TiN film 5 and Ti film 4 are covered with the Pt film 12 so as not to be in contact with the dielectric film. This can prevent defects such as reduction in breakdown voltage even when the adhesion layer and anti-diffusion layer are made of materials that result in such defects when in contact with the dielectric film.

If there is a method of forming a BST film that does not cause reduction in breakdown voltage even when in contact with the TiN film 5 and Ti film 4, such method may be adopted and the Pt film 12 may be omitted.

Then, as shown in FIG. 10, a dielectric film 13 such as BST film and a Pt film 14 for an upper electrode are formed on the entire surface of the semiconductor substrate. Since it is the capacitor structure, the Pt film 14 is insulated from the Pt film 6 by the dielectric film 13.

When patterning the dielectric film 13 and Pt film 14, a third mask film 15 mainly made of Ru or Os is formed on the Pt film 14, and the same process may be performed as those in patterning the Pt film 6 using the first mask film 8, as shown in FIG. 10.

That is, a fourth mask film (not shown) mainly made of silicon oxide or silicon nitride is formed on the third mask film 15, and is patterned by photolithography and etching. Then, the third mask film 15 is etched using the fourth mask film as an etching mask, and the Pt film 14 is patterned by high temperature etching using the patterned third mask film 15 as an etching mask. The dielectric film 13 is also patterned using the third mask film 15 as an etching mask.

While the first mask film 8 is removed to avoid the above-described defects resulting from the contact with the dielectric film 13, the third mask film 15 is not in contact with the dielectric film such as BST film, and hence, does not necessarily need to be removed.

The third mask film 15 mainly made of Ru or Os has the function of preventing penetration of oxygen atoms. Thus, in the case where other components of the semiconductor device are formed in an oxidizing atmosphere, the presence of the third mask film 15 can prevent oxygen from penetrating into the Pt film 14.

While Pt has been described to be used for the respective electrodes by way of example, the description also applies to the case of using Ir for the respective electrodes.

With the method according to the present embodiment, metal films for upper and lower electrodes mainly made of Pt or Ir are selectively etched using the first mask film 8 or third mask film 15, both mainly made of Ru or Os, as a patterning mask.

The use of Ru or Os for a mask material can minimize the aspect ratio of a mask. Thus, pattern collapse hardly occurs different from the case of using silicon oxide for a mask material. As a result, achieved is the method of manufacturing a semiconductor device containing Pt or Ir as an electrode material of capacitors with the high temperature etching technique.

Further, with the method according to the present embodiment, the dielectric film 13 and Pt film 14 are formed after removing the first mask film 8. In the case of using Ru for the main constituent of the first mask film 8, problems of increase in a leakage current and variations in volume of the lower electrode due to oxidation of Ru may arise if the first mask film 8 remains unremoved and constitutes the lower electrode together with the Pt film 6. However, such problems do not arise in the present invention since the first mask film 8 is removed.

Further, the first mask film 8 is selectively etched using the second mask film 10 as an etching mask, thereby performing selective opening of the first mask film 8. Silicon oxide or silicon nitride which is the main constituent of the second mask film 10 has a high etch selectivity to Ru or Os which is the main constituent of the first mask film 8. This allows selective opening of the first mask film 8 to be performed with high accuracy.

Second Preferred Embodiment

A second preferred embodiment is a variation of the method of manufacturing a semiconductor device according to the first preferred embodiment, in which a method of forming a capacitor lower electrode more finely will be described.

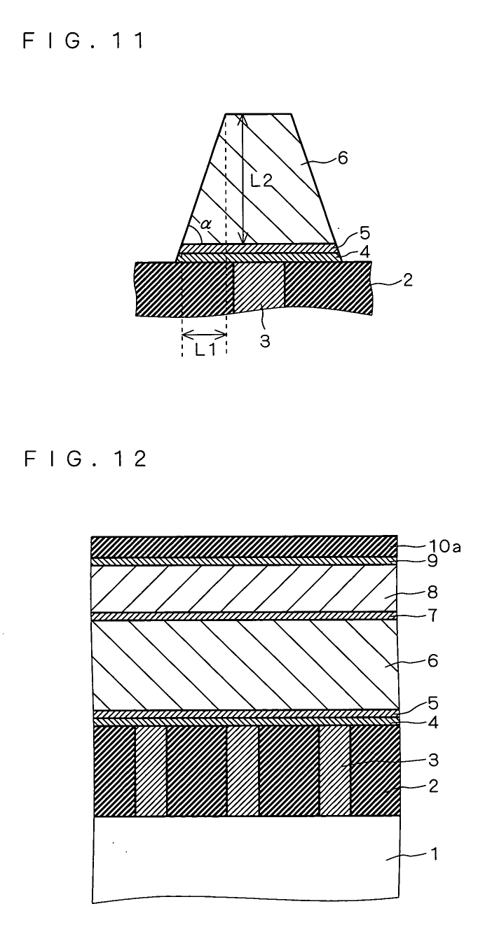

FIG. 11 illustrates taper of the lower electrode. An increment L1 of electrode width given by the taper of the Pt film 6 is expressed using the thickness L2 and the taper angle α of the Pt film 6 as follows: L1=L2×1/tan α. Since an increment L1 is given on each of the right and left sides, an increment of width of this electrode is double the increment L1. When α=85, double the value of 1/tan a is about 0.175.

This means that the electrode width is increased by as much as 17% of the thickness L2 of the Pt film 6. In a lower electrode whose thickness L2 is 200-300 nm, such increment of electrode width exerts a great influence upon the number of devices that can possibly be formed.

Therefore, in the present embodiment, the second mask film 10 as patterned is also subjected to isotropic etching.

FIGS. 12 through 17 illustrate respective steps of a method of manufacturing a semiconductor device according to the present embodiment.

First, as shown in FIG. 12, a structure similar to that of FIG. 2 is prepared in which the interlayer dielectric 2, conductive plugs 3, Ti film 4, TiN film 5, Pt film 6, TiN film 7, first mask film 8, TiN film 9 and a second mask film 10a are formed on the semiconductor substrate 1.

In the present embodiment, the second mask film 10a is formed in a greater thickness than the second mask film 10 shown in FIG. 2. The thickness of the second mask film 10a is 150 nm, for example.

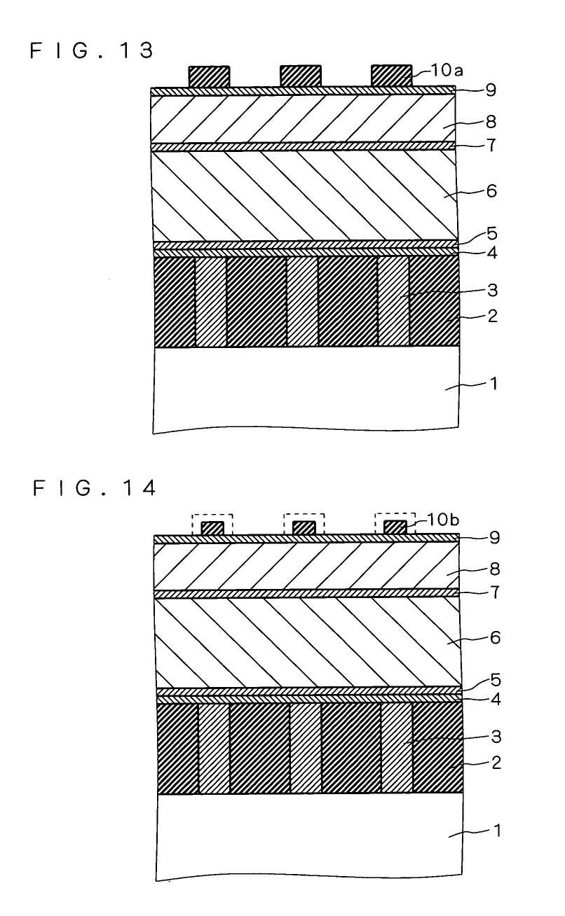

Next, as shown in FIG. 13, the second mask film 10a is patterned by photolithography and etching, similarly to FIGS. 3 and 4.

Subsequently, the patterned second mask film 10a is subjected to isotropic etching as shown in FIG. 14 to form a second mask film 10b of narrower width. This isotropic etching may be achieved by wet etching using aqueous solution of hydrofluoric acid diluted by pure water in the case where the second mask film 10a is made of silicon oxide, for example. In this case, commercially available 50% aqueous solution of hydrofluoric acid may be diluted such that the ratio of pure water to the aqueous solution ranges between 50:1 and 200:1. The electrode width of the second mask film 10b after the isotropic etching shall range between about 0.06 and 0.081 μm, for example. The thickness of the second mask film 10a shall be determined such that the second mask film 10b remains in 100 nm thickness after the isotropic etching.

As a result, the pattern width of the second mask film 10a can be reduced, allowing a capacitor lower electrode to be formed finely.

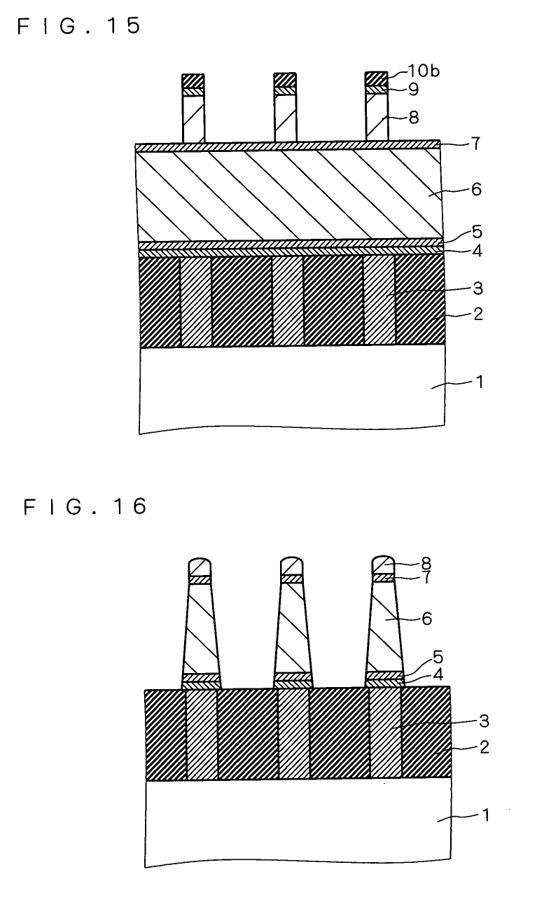

Thereafter, as shown in FIG. 15, the TiN film 9 and first mask film 8 are etched using the second mask film 10b as an etching mask, similarly to FIG. 5.

Next, as shown in FIG. 16, the TiN film 7, Pt film 6, TiN film 5 and Ti film 4 are etched using the first mask film 8 and second mask film 10b as an etching mask, similarly to FIG. 6.

At this time, the patterning mask on Pt has a low aspect ratio of about 3 to 4, which hardly causes problems such as pattern collapse of mask.

In the case where pattern collapse of mask occurs, the second mask film 10b whose thickness is reduced to about 100 nm by isotropic etching is further subjected to anisotropic etching to reduce its thickness to as small as about 15 to 20 nm.

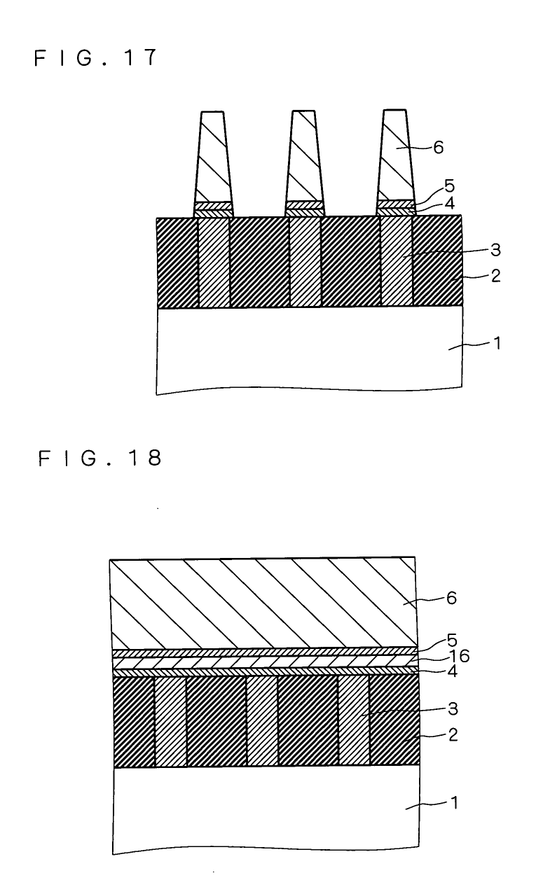

Next, as shown in FIG. 17, the remaining part of the first mask film 8 and TiN film 7 thereunder are removed, similarly to FIG. 7. Then, the Pt film 12, dielectric film 13 and Pt film 14 are formed similarly to FIGS. 8 to 10.

While the second mask film 10a is subjected to isotropic etching to reduce the electrode width in the foregoing description, the first mask film 8 may directly be subjected to isotropic etching.

A plasma processing in an oxidizing atmosphere which is generally employed in removing photoresist allows isotropic etching to be also performed on Ru or Os. Thus, the pattern width of the first mask film 8 can further be reduced by conducting a plasma processing on the first mask film 8 in an oxidizing atmosphere whether or not the second mask film 10a has been subjected to isotropic etching. As a result, the capacitor lower electrode can be formed finely.

In this case, the first mask film 8 is subjected to isotropic etching after the processes shown in FIGS. 1 through 5 described in the first preferred embodiment, thereby forming the structure shown in FIG. 15. Then, the processes shown in FIG. 16 and thereafter are performed.

Third Preferred Embodiment

A third preferred embodiment is a variation of the method according to the second preferred embodiment, in which a film mainly made of Ru or Os is formed as an etching stopper employed in etching the Pt film 6.

FIGS. 18 through 24 illustrate respective steps of the method according to the present embodiment.

First, as shown in FIG. 18, a structure similar to that of FIG. 1 is prepared in which the interlayer dielectric 2, conductive plugs 3, Ti film 4, an etching stopper film 16, the TiN film 5 and Pt film 6 are formed on the semiconductor substrate 1. Different from the structure of FIG. 1, the etching stopper film 16 mainly made of Ru or Os is formed between the Ti film 4 and TiN film 5.

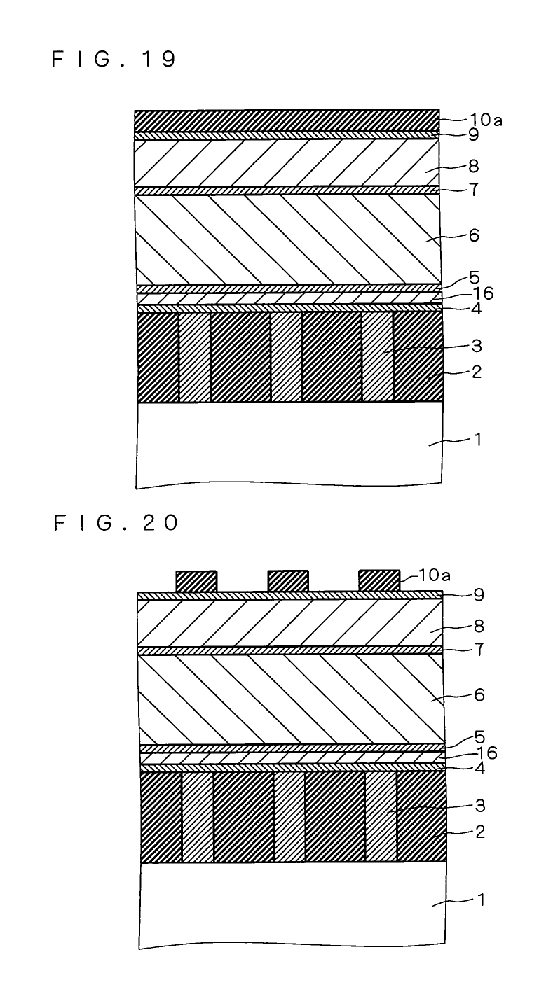

Then, as shown in FIG. 19, the TiN film 7, first mask film 8, TiN film 9 and second mask film 10a are formed on the Pt film 6, similarly to FIG. 12.

Next, as shown in FIG. 20, the second mask film 10a is patterned, similarly to FIG. 13.

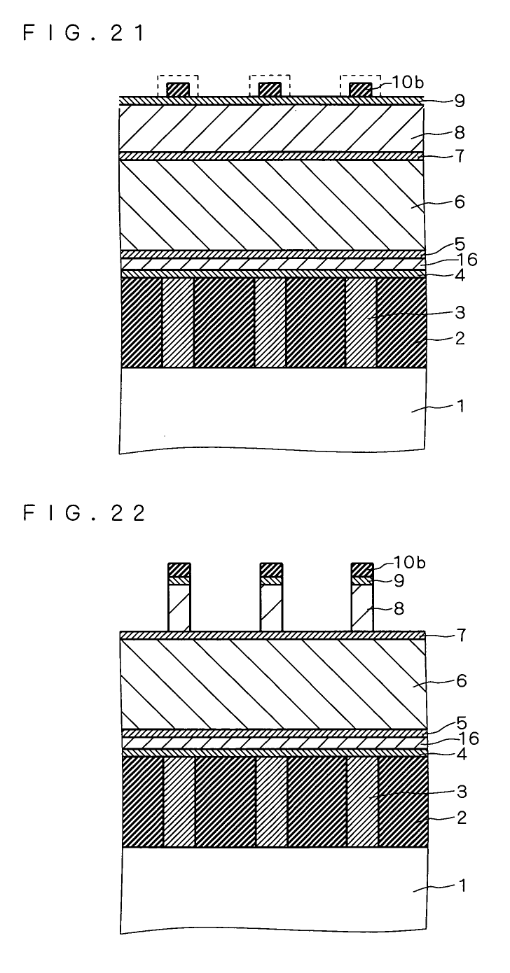

Subsequently, as shown in FIG. 21, the patterned second mask film 10a is subjected to isotropic etching to form the second mask film 10b of narrower width, similarly to FIG. 14.

Then, as shown in FIG. 22, the TiN film 9 and first mask film 8 are etched using the second mask film 10b as an etching mask, similarly to FIG. 15.

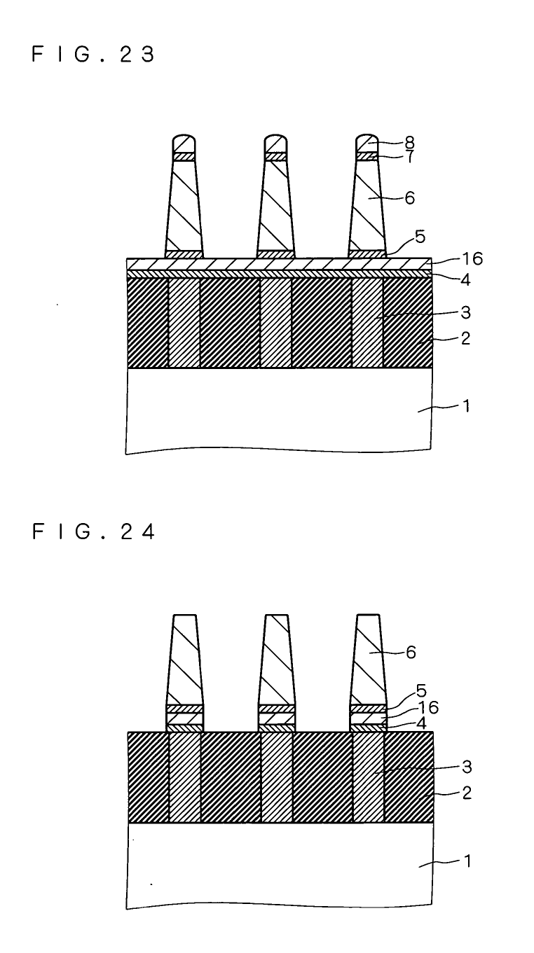

Next, as shown in FIG. 23, the TiN film 7, Pt film 6 and TiN film 5 are etched using the first mask film 8 and second mask film 10b as an etching stopper, similarly to FIG. 16.

At this time, the etching stopper film 16 having the same main constituent as the first mask film 8 is used as an etching stopper for the Pt film 6. This prevents the surface of the underlying layer from being damaged in etching the metal film for the lower electrode.

Further, the etching stopper film 16 mainly made of Ru or Os has the function of preventing penetration of oxygen atoms. The presence of this etching stopper film 16 can prevent oxygen from penetrating into the conductive plugs 3 in the underlying layer from the Pt film 6 in an oxidizing atmosphere in forming the dielectric film 13.

Being interposed between the etching stopper film 16 and Pt film 6, the TiN film 5 functions as an anti-diffusion layer for preventing interdiffusion of atoms between the etching stopper film 16 and Pt film 6.

As a material other than TiN, at least one of metal oxide, metal nitride, metal silicide, metal oxynitride, metal silicon-oxide, metal silicon-oxynitride and metal silicon-nitride may suitably be selected to perform the same function as the TiN film 5, as has been described in the first preferred embodiment.

Next, as shown in FIG. 24, the remaining part of the first mask film 8 and TiN film 7 thereunder and the etching stopper film 16 and Ti film 4 thereunder are removed, similarly to FIG. 17. Then, the Pt film 12, dielectric film 13 and Pt film 14 are formed similarly to FIGS. 8 to 10.

The presence of the Pt film 12 can prevent the dielectric film 13 and etching stopper film 16 from being in contact with each other. In the case of using a BST film for a dielectric film, a leakage current may be generated if the BST film is in contact with the etching stopper film 16 mainly made of Ru or Os. However, the Pt film 12 can prevent such defects.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device comprising the steps of:
(a) forming a capacitor electrode metal film mainly made of one of Pt and Ir on an underlying layer;
(b) forming a first mask film mainly made of one of Ru and Os on said capacitor electrode metal film;
(c) selectively opening said first mask film;
(d) exposing an uncovered part of said capacitor electrode metal film at an opening of said first mask film to a predetermined gas atmosphere so as to volatilize while heating said capacitor electrode metal film, thereby selectively etching said capacitor electrode metal film; and
(e) removing said first mask film.

2. The method according to claim 1, wherein
said capacitor electrode metal film is a lower electrode metal film of a capacitor,
said method further comprising the steps of:
(f) after said step (e), forming a dielectric film covering said lower electrode metal film; and
(g) forming, on said dielectric film, an upper electrode insulated from said lower electrode metal film by said dielectric film.

3. The method according to claim 2, wherein
a conductive plug is formed in said underlying layer and a first metal film is formed on said underlying layer to be in contact with said conductive plug, and
in said step (a), said lower electrode metal film is formed to be connected to said conductive plug with said first metal film interposed therebetween.

4. The method according to claim 3, wherein
a second metal film is further formed on said first metal film, said second metal film containing at least one material selected from the group consisting of metal oxide, metal nitride, metal silicide, metal oxynitride, metal silicon-oxide, metal silicon-oxynitride and metal silicon-nitride, and
in said step (a), said lower electrode metal film is formed to be connected to said first metal film with said second metal film interposed therebetween.

5. The method according to claim 3, further comprising the step of
(h) in advance of said step (f), forming a contact-preventing metal film preventing contact between said dielectric film and said first metal film.

6. The method according to claim 1, further comprising the step of
(i) in advance of said step (b), forming a first metal film on said capacitor electrode metal film, said first metal film containing at least one material selected from the group consisting of metal oxide, metal nitride, metal silicide, metal oxynitride, metal silicon-oxide, metal silicon-oxynitride and metal silicon-nitride, and
in said step (b), said first mask film is formed on said capacitor electrode metal film with said first metal film therebetween.

7. The method according to claim 1, wherein
said step (c) includes the steps of:
(c-1) forming a second mask film containing at least one of silicon oxide and silicon nitride on said first mask film;
(c-2) patterning said second mask film by photolithography and etching; and
(c-3) selectively etching said first mask film using said second mask film as an etching mask, thereby selectively opening said first mask film.

8. The method according to claim 7, wherein
said step (c) further includes the step of
(c-4) in advance of said step (c-1), forming a first metal film on said first mask film, said first metal film containing at least one material selected from the group consisting of metal oxide, metal nitride, metal silicide, metal oxynitride, metal silicon-oxide, metal silicon-oxynitride and metal silicon-nitride, and
in said step (c-1), said second mask film is formed on said first mask film with said first metal film therebetween.

9. The method according to claim 7, wherein
in said step (c-2), said second mask film as patterned is subjected to isotropic etching.

10. The method according to claim 1, further comprising the step of
(j) after said step (c), performing isotropic etching on said first mask film.

11. The method according to claim 1, wherein
an etching stopper film mainly made of one of Ru and Os is formed on said underlying layer,
in said step (a), said capacitor electrode metal film is formed on said etching stopper film, and
in said step (d), said etching stopper film is used as an etching stopper in etching said capacitor electrode metal film.

12. The method according to claim 11, wherein
a first metal film is formed on said etching stopper film, said first metal film containing at least one material selected from the group consisting of metal oxide, metal nitride, metal silicide, metal oxynitride, metal silicon-oxide, metal silicon-oxynitride and metal silicon-nitride, and
said capacitor electrode metal film is formed on said etching stopper film with said first metal film therebetween.

13. The method according to claim 11, wherein
said capacitor electrode metal film is a lower electrode metal film of a capacitor,
said method further comprising the steps of:
(f) after said step (e), forming a dielectric film covering said lower electrode metal film;
(g) forming, on said dielectric film, an upper electrode insulated from said lower electrode metal film by said dielectric film; and
(k) in advance of said step (f), forming a contact-preventing metal film preventing contact between said dielectric film and said etching stopper film.

14. The method according to claim 2, wherein
said step (g) includes the steps of:
(g-1) forming, on said dielectric film, an upper electrode metal film insulated from said lower electrode metal film by said dielectric film;
(g-2) forming a third mask film mainly made of one of Ru and Os on said upper electrode metal film;
(g-3) selectively opening said third mask film; and
(g-4) exposing an uncovered part of said upper electrode metal film at an opening of said third mask film to a predetermined gas atmosphere so as to volatilize while heating said upper electrode metal film, thereby selectively etching said upper electrode metal film.
